(19) United States
(12) Patent Application Publication
(10) Pub. No.: US 2022/0130733 A1
(43) Pub. Date: Apr. 28, 2022

(54) SEMICONDUCTOR DEVICE INCLUDING A TEST DUMMY PATTERN, METHOD OF MANUFACTURING THE SEMICONDUCTOR DEVICE AND METHOD OF INSPECTING AN ERROR USING THE TEST DUMMY PATTERN

(71) Applicant: SK hynix Inc., Icheon-si Gyeonggi-do (KR)

(72) Inventors: Jae Taek KIM, Icheon-si Gyeonggi-do (KR); Hye Yeong JUNG, Icheon-si Gyeonggi-do (KR)

(73) Assignee: SK hynix Inc., Icheon-si Gyeonggi-do (KR)

(21) Appl. No.: 17/208,903

(22) Filed: Mar. 22, 2021

(30) Foreign Application Priority Data
Oct. 22, 2020 (KR) 10-2020-0137568

(51) Int. Cl. H01L 21/66; G01R 31/26; G01N 23/2251

(52) U.S. Cl. CPC H01L 22/32; G01N 23/2251; G01R 31/2644; H01L 22/12

(57) ABSTRACT

In a method of inspecting an error, a lower wiring structure may be formed. A main dummy pattern and a test dummy pattern may be formed on the lower wiring structure, The main dummy pattern may include a via pattern and a wiring pattern having a width greater than a width of the via pattern. The test dummy pattern may be spaced apart from the main dummy pattern by no less than a critical distance. The test dummy pattern may have a width substantially the same as that of the via pattern. The test dummy pattern may have a height substantially the same as that of the main dummy pattern. The test dummy pattern may then be tested to predict an error of the main dummy pattern based on an error of the test dummy pattern.

### CROSS-REFERENCES TO RELATED APPLICATION

The present application claims priority under 35 U.S.C. § 119(a) to Korean application number 10-2020-0137568, filed on Oct. 22, 2020, in the Korean Intellectual Property Office, which is incorporated herein by reference in its entirety.

### BACKGROUND

### 1. Technical Field

Various embodiments may generally relate to a semiconductor-related technology, more particularly to a semiconductor device including a test dummy pattern, a method of manufacturing the semiconductor device, and a method of inspecting an error using the test dummy pattern.

### 2. Related Art

Recently, a damascene wiring, which may be configured to simultaneously form a contact wiring and a wiring, as a wiring structure of a semiconductor integrated circuit device may be widely used. In the damascene wiring, after forming a hole through an insulating interlayer, the hole may be filled with a conductive material without an etching process so that various wiring materials may be used.

In forming the wiring structure, a process for inspecting the wiring structure may be performed to determine whether the wiring structure may be normal or not. Generally, any one of wafers manufactured in a same lot may be selected. A contact pattern may be formed on the selected wafer. Whether the contact may make contact with a lower conductive pattern or not may be tested to monitor a contact failure. This inspection process may be referred to as a wafer reject process. A rejected wafer may then be scrapped.

However, because the contact pattern and the wiring in the damascene structure may be simultaneously formed, it may be difficult to inspect an error of each of the contact patterns.

### SUMMARY

In some embodiments of the present disclosure, a semiconductor device may include a main dummy pattern and a test dummy pattern spaced apart from each other by a critical distance. The main dummy pattern may have a damascene structure including a via pattern and a wiring pattern formed on the via pattern. The via pattern may have a first width. The wiring pattern may have a second width wider than the first width. The test dummy pattern may include a bottom surface and an upper surface. The bottom surface may have the first width. The bottom surface may be substantially coplanar with a bottom surface of the via pattern. The upper surface may be substantially coplanar with an upper surface of the wiring pattern.

In some embodiments of the present disclosure, a semiconductor device may include a semiconductor substrate, a lower insulating interlayer, an upper insulating interlayer, a main dummy pattern and a test dummy. The semiconductor substrate may include a lower wiring structure. The lower insulating interlayer may be formed on the lower wiring structure. The upper insulating interlayer may be formed on the lower insulating interlayer. The main dummy pattern includes a via contact with a first width formed in the lower insulating interlayer and a trench wiring pattern formed on the via contact, the trench wiring pattern having a second width wider than the first width of the via contact. The via contact may be formed in the lower insulating interlayer. The via contact may have a first width. The trench wiring pattern may be formed in the upper insulating interlayer. The trench wiring pattern may have a second width wider than the first width. The test dummy pattern may be formed through the lower insulating interlayer and the upper insulating interlayer. The test dummy pattern may have the first width. The test dummy pattern may include an error of the main dummy pattern.

In some embodiments of the present disclosure, according to a method of manufacturing a semiconductor device, a lower wiring structure may be formed on a semiconductor substrate. A lower insulating interlayer may be formed on the lower wiring structure. An upper insulating interlayer may be formed on the lower insulating interlayer. The upper insulating interlayer and the lower insulating interlayer may be etched until the lower wiring structure may be exposed to form a first via hole having a first width and a second via hole having a second width. The upper insulating interlayer with the first via hole may be etched to form a wiring hole, which may have the second width, connected to the first via hole. The wiring hole, the first via hole and the second via hole may be filled with a conductive layer to form a main dummy pattern and a test dummy pattern having a same height.

In some embodiments of the present disclosure, according to a method of inspecting an error, a lower wiring structure may be formed. A main dummy pattern and a test dummy pattern may be formed on the lower wiring structure. The main dummy pattern may include a via pattern and a wiring pattern having a width greater than a width of the via pattern. The test dummy pattern may be spaced apart from the main dummy pattern by no less than a critical distance. The test dummy pattern may have a width substantially the same as that of the via pattern. The test dummy pattern may have a height substantially the same as that of the main dummy pattern. The test dummy pattern may then be tested to predict an error of the main dummy pattern based on an error of the test dummy pattern.

### BRIEF DESCRIPTION OF THE DRAWINGS

The above and another aspects, features and advantages of the subject matter of the present disclosure will be more dearly understood from the following detailed description taken in conjunction with the accompanying drawings, in which:

FIG. 1 is an exploded perspective view illustrating a semiconductor device in accordance with various embodiments;

FIG. 2 is a plan view illustrating a semiconductor device in accordance with various embodiments;

FIGS. 3 and 4 are plan views illustrating a dummy region in accordance with various embodiments;

FIG. 5 is a cross-sectional view taken along a line a-a′ in FIGS. 3 and 4;

FIGS. 6 to 9 are cross-sectional views illustrating a method of forming a dummy region including a test dummy pattern for an error inspection in accordance with various embodiments;

FIG. 10 is a flow chart illustrating a method of inspecting an error in accordance with various embodiments;

FIG. 11 is a flow chart illustrating an EBI test operation in accordance with various embodiments;

FIG. 12 is a block diagram illustrating an electron beam apparatus in accordance with various embodiments; and

FIGS. 13 and 14 are images illustrating an intensity of a secondary electron signal in accordance with various embodiments,

### DETAILED DESCRIPTION

Various embodiments will be described with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present application as defined in the appended claims.

The present disclosure is described herein with reference to cross-section and/or plan illustrations of idealized embodiments of the present disclosure. However, embodiments should not be construed as limiting the concepts. Although a few embodiments of the will be shown and described, it will be appreciated by those of ordinary skill in the art that changes may be made in these embodiments without departing from the principles and spirit of the present disclosure.

Terms such as a semiconductor wafer, a wafer, a substrate, a wafer substrate, a partially manufactured integrated circuit, etc., may be reciprocally used exchangeably. However, the substrate may indicate the semiconductor wafer.

Same reference numerals refer to same elements throughout the specification. Thus, even though a reference numeral is not mentioned or described with reference to a drawing, the reference numeral may be mentioned or described with reference to another drawing. In addition, even though a reference numeral is not shown in a drawing, it may be mentioned or described with reference to another drawing.

According to some embodiments, in order to detect the contact failure of the main dummy pattern having the damascene structure, the test dummy pattern as the via pattern may be formed at the position spaced from the main dummy pattern by the critical distance. The contact failure of the test dummy pattern may be inspected to predict the contact failure of the main dummy pattern. Thus, an additional wafer reject process might not be required to prevent an unnecessary waste of the wafer. Further, the contact failure of the damascene wiring structure, which might not be detected by an EBI inspected, may be accurately predicted.

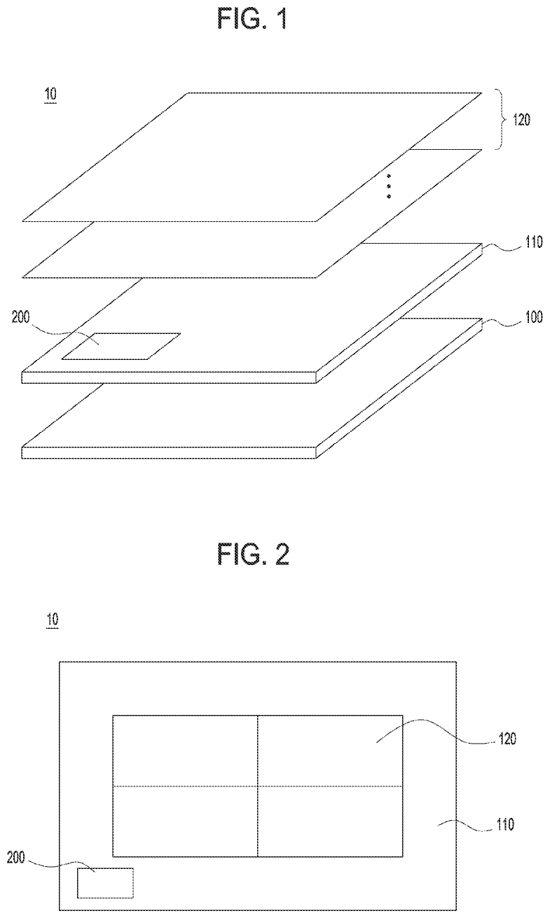

FIG. 1 is an exploded perspective view illustrating a semiconductor device in accordance with some embodiments.

Referring to FIG. 1, a semiconductor chip 10 may include a peripheral/core region 110 and a memory cell region 120.

The peripheral/core region 110 may include various circuit elements configured to control operations of the memory cell region 120. The peripheral/core region 110 may be arranged on a semiconductor substrate 100. The semiconductor substrate 100 may include a silicon substrate, a GaAs substrate, a compound semiconductor substrate, a silicon-on-insulator (SOI) substrate, etc.

The memory cell region 120 may include a plurality of memory cells. The memory cell region 120 may be arranged on the peripheral/core region 110. The memory cell region 120 may be electrically connected with the peripheral/core region 110 through wiring structures vertically extended with respect to a surface of the semiconductor substrate 100. The memory cell region 120 may have a stack structure.

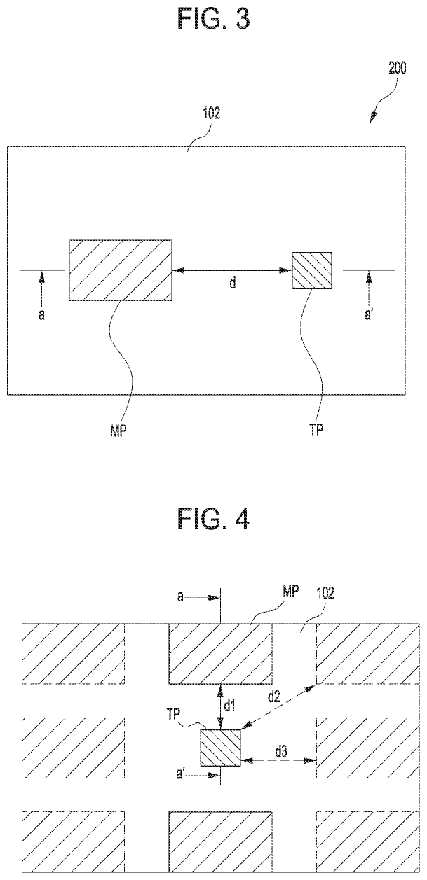

FIG. 2 is a plan view illustrating a semiconductor device in accordance with some embodiments.

Referring to FIG. 2, the peripheral/core region 110 and the memory cell region 120 may be arranged on a same plane of the semiconductor substrate. When the peripheral/core region 110 and the memory cell region 120 may be positioned on the same plane, the peripheral/core region 110 may be located at a peripheral region of the memory cell region 120.

Referring to FIGS. 1 and 2, a dummy region 200 may be arranged at a portion of the peripheral/core region 110. The dummy region 200 may have a dummy shape corresponding to the wiring structures formed in the memory cell region 120. Further, the dummy region 200 may have a dummy element shape corresponding to elements formed in the memory cell region 120.

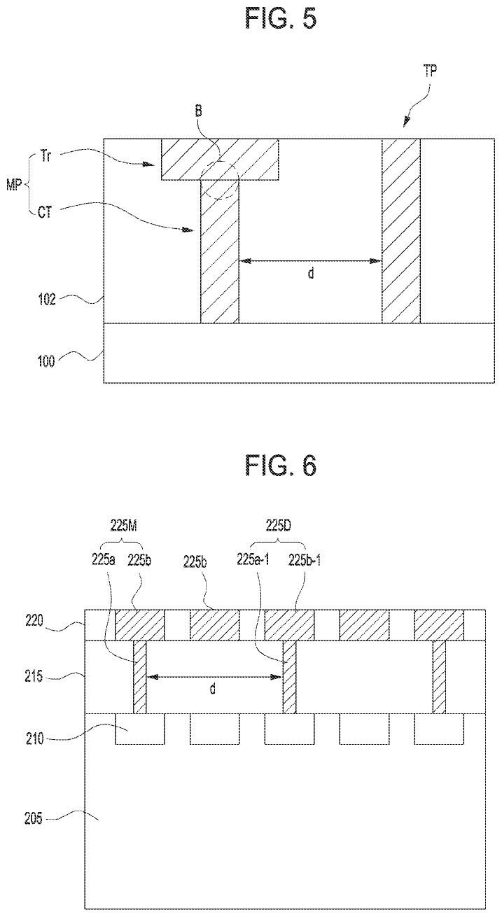

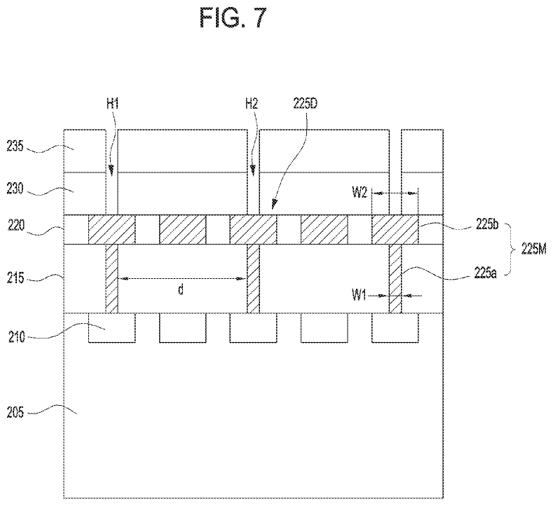

FIGS. 3 and 4 are plan views illustrating a dummy region in accordance with some embodiments, and FIG. 5 is a cross-sectional view taken along a line a-a′ in FIGS. 3 and 4.

Referring to FIG. 3, the dummy region 200 may include a main dummy pattern MP and a test dummy pattern TP. The main dummy pattern MP may include a damascene wiring structure as a tested object. The test dummy pattern TP may be spaced apart from the main dummy pattern MP by a critical distance d. For example, the main dummy pattern MP and the test dummy pattern TP is separated by an insulation layer 102.

However, a position of the test dummy pattern TP might not be restricted on the dummy region 200. Further, it may be required to form the critical distance d between the test dummy pattern TP and the main dummy pattern MP.

To explain this in detail, as a semiconductor device may have been highly integrated, wirings and contacts may be densely arranged. Because the wirings and the contacts may have a minimum pitch in a pattern dense region, a precise fabrication process may be required. Thus, recipes of semiconductor fabrication processes may be set based on the wirings and the contacts in the pattern dense region. As a result, errors of the wirings and contacts may be generated more in a pattern sparse area compared to the pattern dense region.

Therefore, the main dummy pattern MP of some embodiments may have a structure formed by modeling a damascene wiring in the pattern dense region. The test dummy pattern TP of some embodiments may have a structure formed by modeling a conductive pattern or a damascene pattern in the pattern sparse area. The critical distance d between the main dummy pattern MP and the test dummy pattern TP may be interpreted as a minimum distance between the pattern dense region and the pattern sparse area for determining an error range of the pattern sparse region.

Thus, as shown in FIG. 4, positions d1, d2, d3, . . . of the test dummy pattern TP may be spaced apart from a plurality of the main dummy patterns MP by no less than the critical distance d. For example, the main dummy pattern MP and the test dummy pattern TP is separated by an insulation layer 102.

However, as shown in FIG. 5, the main dummy pattern MP may have a damascene structure in the insulation layer 102. The main dummy pattern MP may include a via contact CT and a trench wiring pattern Tr. The via contact CT may have a first width. The trench wiring pattern Tr may have a second width wider than the first width. A boundary face B might not exist between the trench wiring pattern Tr and the via contact CT if the trench wiring pattern Tr and the via contact pattern are formed of the same material or the trench wiring pattern Tr and the via contact pattern are formed at the same time.

The trench wiring pattern Tr and the via contact CT in the damascene structure may be simultaneously formed, the boundary face might not exist between the trench wiring pattern Tr and the via contact CT. The trench via pattern Tr and the via contact CT may be successively formed without the boundary face so that it may be difficult to inspect whether the via contact CT may be normally formed or not.

The via contact CT or a general contact structure (for example, a contact plug having a substantially same width for connecting an upper interconnecting line and a lower interconnecting line) may be tested by an electron beam inspection (EBI). The EBI inspection may include irradiating an electron beam to a target region of the semiconductor chip (10 of FIG. 2), for example, the dummy region, and measuring an intensity of a second electron signal reflected from the target region to detect an error of the target region.

However, when the main dummy pattern MP has the damascene structure, the trench wiring pattern Tr may have a shape different from that of the via contact CT, the error of the via contact CT might not be detected using the EBI. U.S. Pat. No. 9,859,150, which is herein incorporated by reference for all that in contains, discloses the damascene structure comprising a trench wiring and a via contact.

According to some embodiments, the test dummy pattern TP, which may have the first width substantially the same as a width of the via contact CT, may be formed at a region, which may be spaced apart from the main dummy pattern MP by the critical distance d, in which error probability may be high. Thus, an error of the test dummy pattern TP in place of checking the error of the via contact CT of the main dummy pattern MP may be checked to predict the error of the main dummy pattern MP. The test dummy pattern TP may have the first width with respect to a total height without formation of the trench wiring pattern Tr. Thus, the error of the main dummy pattern MP may be predicted by results of the EBI on the test dummy pattern TP.

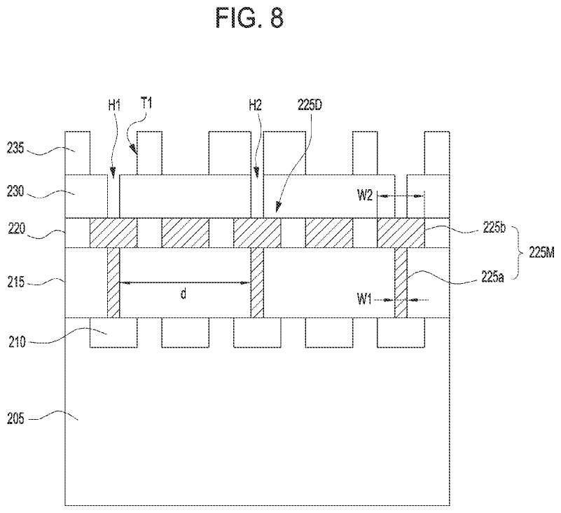

FIGS. 6 to 9 are cross-sectional views illustrating a method of forming a dummy region including a test dummy pattern for an error inspection in accordance with some embodiments.

Referring to FIG, 6, an isolation layer 210 may be formed at a portion of a semiconductor substrate 205 corresponding to the dummy region (200: refer to FIG. 3). For example, the isolation layer 210 may be located within the dummy region 200. The isolation layer 210 of the dummy region 200 may be formed at the same time as the isolation layer (not shown) of the peripheral/core region 110 (refer to FIG. 1 or 2). The isolation layer 210 may have a shallow trench isolation (STI) structure. A first insulating interlayer 215 may be formed on the semiconductor substrate 205 with the isolation layer 210. A lower contact 225a of the main dummy pattern MP and a lower contact 225a-1 of the test dummy pattern TP may be formed in the first insulating interlayer 215. The lower contacts 225a and 225a-1 may be spaced apart from each other by the critical distance d. The lower contacts 225a and 225a-1 may have a first width W1. In FIG. 6, the contacts 225a and 225a-1 may be formed on the isolation layer 210, not restricted within the above-mentioned structure.

A second insulating interlayer 220 may be formed on the first insulating interlayer 215. Trench patterns 225b and 225b-1 of the main dummy pattern MP and the test dummy pattern TP may be formed in the second insulating interlayer 220. The trench patterns 225b and 225b-1 may have a second width W2 wider than the first width W1. The trench patterns 225b and 225b-1 may he selectively formed on the contacts 225a and 225a-1 to form a preliminary main dummy pattern 225M and a preliminary test dummy pattern 225D.

In some embodiments, the contacts and the trench patterns in the preliminary main dummy pattern 225M and the preliminary test dummy pattern 225D may have a damascene structure or a general contact structure.

Referring to FIG. 7, a third insulating interlayer 230 may be formed on the second insulating interlayer 220. For example, the third insulating interlayer 230 may include a material having an etching selectivity with respect to a material of the second insulating interlayer 220. For example, the material of the third insulating interlayer 230 may be substantially the same as that of the first insulating interlayer 215.

A fourth insulating interlayer 235 may be formed on the third insulating interlayer 230. The fourth insulating interlayer 235 may include a material having an etching selectivity with respect to the material of the third insulating interlayer 230. For example, the material of the fourth insulating interlayer 235 may be substantially the same as that of the second insulating interlayer 220.

The fourth insulating interlayer 235 and the third insulating interlayer 230 may be etched using a first etch mask under a same etch recipe to form a first via hole H1 and a second via hole H2. The first etch mask may have an opening corresponding to the first width to provide the first and second via holes H1 and H2 with the first width. The first via hole H1 and the second via hole H2 may be positioned over the preliminary main dummy pattern 225M and the preliminary test dummy pattern 225d. The first via hole H1 may be located over the preliminary main dummy pattern 225M. The second via hole H2 may be located over the preliminary test dummy pattern 225D.

Referring to FIG. 8, the fourth insulating interlayer 235 may be etched using a second etch mask to form a wiring hole T1. The second etch mask may have an opening corresponding to the second width wider than the first width. The second etch mask may be configured to expose the first via hole H1 and to block the second via hole H2. Thus, the wiring hole T1 defined by the second etch mask may be connected to the first via hole H1.

The wiring hole T1 in the fourth insulating interlayer 235 may be connected to the first via hole H1 over the preliminary main dummy pattern 225M. Thus, a template for forming the main dummy pattern and the test dummy pattern may be formed in the third insulating interlayer 230 and the fourth insulating interlayer 235.

Referring to FIG. 9, a conductive layer may be formed on the fourth insulating interlayer 235 to fill the first via hole H1, the second via hole H2 and the wiring hole T1. The conductive layer may include a material having good gap-filling characteristic such as tungsten. The conductive layer on the fourth insulating interlayer 235 may be removed by a chemical mechanical polishing (CMP) process. Thus, the main dummy pattern MP and the test dummy pattern TP may be formed in the third insulating interlayer 230 and the fourth insulating interlayer 235. The main dummy pattern MP may include a via pattern 240a and a wiring pattern 240b. The test dummy pattern TP may include an extended via pattern 240c.

The test dummy pattern TP may have a bottom surface substantially coplanar with a bottom surface of the via pattern 240a in the main dummy pattern MP, and an upper surface substantially coplanar with an upper surface of the wiring pattern 240b in the main dummy pattern MP. Further, the extended via pattern 240c of the test dummy pattern TP may have a width substantially the same as that of the via pattern 240a. Thus, because the bottom surface and a lower structure of the test dummy pattern TP may be substantially the same as those of the via pattern 240a of the main dummy pattern MP having the damascene structure, an error of the main dummy pattern MP, i.e., a contact failure of damascene patterns may be predicted by results of the EBI test.

Particularly, although the shape of the test dummy pattern TP may be different from the shape of the main dummy pattern MP, the first via hole H1 configured to provide the template of the via pattern 240a and the second via hole H2 configured to provide the template of the test dummy pattern TP may be simultaneously formed. Thus, a contact not-open failure of the first via hole H1 and the main dummy pattern MP may be accurately predicted by the test results from the second via hole H2 and the test dummy pattern TP. A method of predicting the error may be illustrated later. The words “simultaneous” and “simultaneously” as used herein with respect to occurrences mean that the occurrences take place on overlapping intervals of time. For example, of a first occurrence takes place over a first interval of time and a second occurrence takes place simultaneously over a second interval of time, then the first and second intervals at least partially overlap each other such that there exists a time at which the first and second occurrences are both taking place.

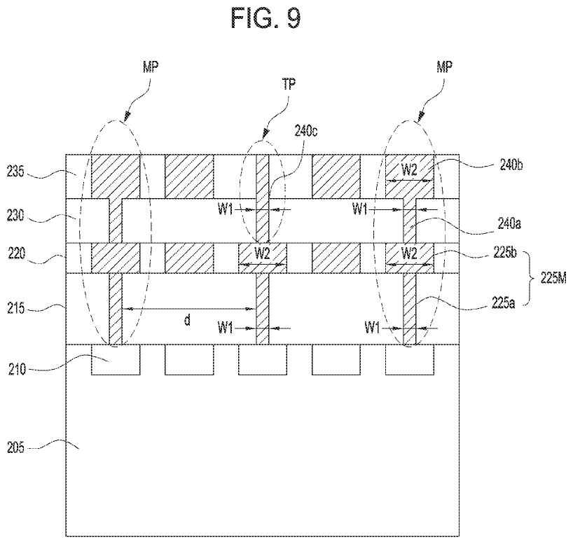

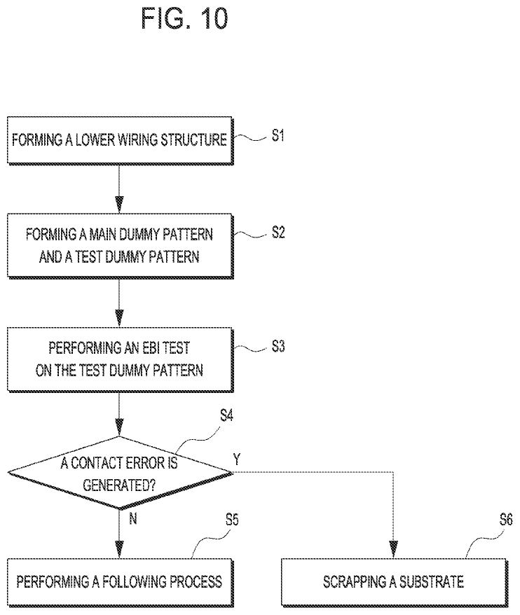

FIG. 10 is a flow chart illustrating a method of inspecting an error in accordance with some embodiments, and FIG. 11 is a flow chart illustrating an EBI test operation in accordance with some embodiments.

Referring to FIGS. 5 to 10, in step S1, a lower wiring structure may be formed on a dummy region 200. The lower wiring structure may include a preliminary main dummy pattern 225M and a preliminary test dummy pattern 225D. In FIGS. 5 to 10, the preliminary main dummy pattern 225M and the preliminary test dummy pattern 225D may be formed by a damascene process. Alternatively, the preliminary main dummy pattern 225M and the preliminary test dummy pattern 225D may be formed by a general contact and wiring formation method.

In step S2, a via pattern 240a and a wiring pattern 240b may be formed on the preliminary main dummy pattern 225M by the processes illustrated with reference to FIGS. 5 to 9 to form the main dummy pattern MP. Simultaneously, a extended via pattern 240c may be formed on the preliminary test dummy pattern 225D to form the test dummy pattern TP.

In step S3, the EBI test may be performed on the test dummy pattern TP.

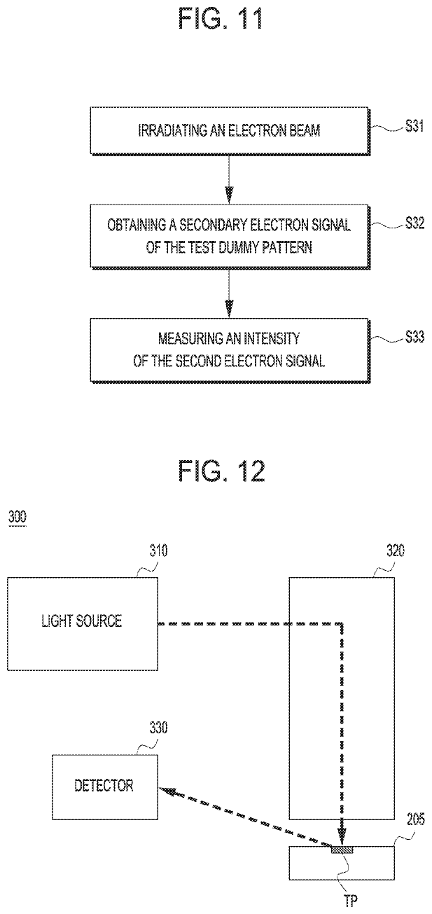

FIG. 12 is a block diagram illustrating an electron beam apparatus in accordance with some embodiments.

Referring to FIG. 12, an electron beam apparatus 300 may include a light source 310, an optical system 320 and a detector 330,

The light source 310 may include an electron gun configured to generate an electron beam.

The optical system 320 may concentrate the electron beam generated from the light source 310 to irradiate the electron beam to the test dummy pattern TP of the semiconductor substrate 205 (531). The optical system 320 may include a plurality of optical elements such as condensing lenses.

The detector 330 may receive a light reflected from the test dummy pattern TP to detect an error of the test dummy pattern TP. The detector 330 may detect a secondary electron signal reflected from the test dummy pattern TP to form an image including an intensity of the detected secondary electron signal (532).

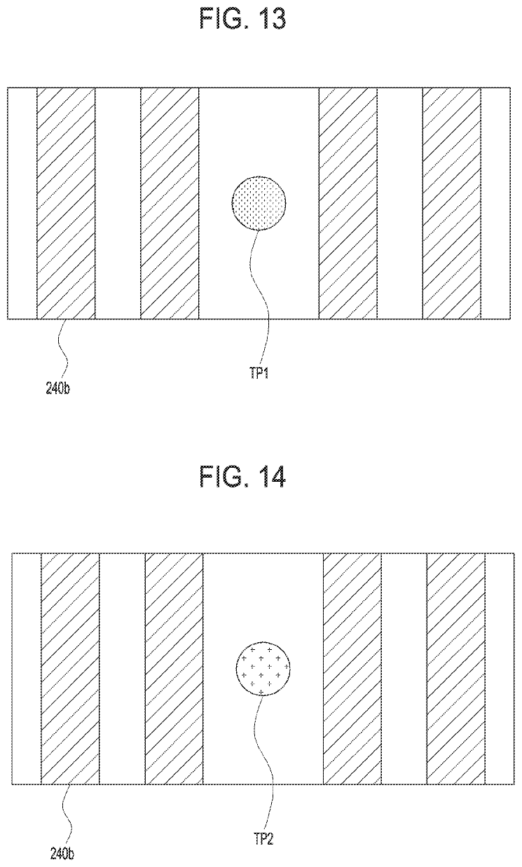

FIGS. 13 and 14 are images illustrating an intensity of a secondary electron signal in accordance with some embodiments.

For example, when the second via hole H2 is formed in the third insulating interlayer 230 and the fourth insulating interlayer 235 to fully expose the preliminary test dummy pattern 225D, the test dummy pattern TP may make contact with the preliminary test dummy pattern 225D to normally form the test dummy pattern TP. The electron beam incident to the normally formed test dummy pattern TP may be absorbed in the test dummy pattern TP so that the second electron beam reflected from the test dummy pattern TP may be a small quantity. Thus, as shown in FIG. 13, the secondary electron signal reflected from the normal test dummy pattern TP may be about zero to form a solid image. In FIG. 13, a reference numeral TP1 may represent the normal test dummy pattern TP.

In contrast, when the second via hole H2 is formed in the third insulating interlayer 230 and the fourth insulating interlayer 235 to not expose the preliminary test dummy pattern 225D, the test dummy pattern TP might not make contact with the preliminary test dummy pattern 225D to generate the contact error. The electron beam irradiated to the test dummy pattern TP with the contact error may be reflected from the fourth insulating interlayer 235 remaining between the preliminary test dummy pattern 225D and the second via hole H2, thereby generating a secondary electron signal having an intensity higher than that of the secondary electron signal from the normal test dummy pattern TP (532). Thus, as shown in FIG. 14, an image TP2 of the test dummy pattern TP with the contact error may have a brightness greater than that of the image TP1 of the normal test dummy pattern TP. For example, the images TP1 and TP2 of the test dummy patterns TP may be obtained from a scanning electron microscope (SEM).

Although not depicted in FIG. 12, the electron beam apparatus may further include a control block. In step S4, the control block may determine the generation of the contact error based on the images TP1 and TP2 of the test dummy pattern TP provided from the detector 330.

In step S5, when the contact error is not generated in the test dummy pattern TP, following processes may then be performed.

In contrast, when the contact error is generated in the test dummy pattern TP, in step S6, a corresponding substrate may be determined as the contact error so that the substrate may then be scrapped.

Further, the method may further include a process for resetting an etching recipe of the first and second via holes H1 and H2 based on the information of the contact error. Thus, the error of the first and second via holes H1 and H2 such as a not-open may be prevented in a following damascene wiring process. The not-open is a phenomenon in which a contact surface is not completely exposed when the contact hole is formed.

According to some embodiments, in order to detect the contact failure of the main dummy pattern having the damascene structure, the test dummy pattern as the via pattern may be formed at the position spaced from the main dummy pattern by the critical distance. The contact error of the test dummy pattern may be inspected to predict the contact failure of the main dummy pattern. Thus, an additional wafer reject process might not be required to prevent an unnecessary waste of the wafer. Further, the contact error of the damascene wiring structure, which might not be detected by an EBI inspected, may be accurately predicted.

The above described embodiments of the present disclosure are intended to illustrate and not to limit the present disclosure. Various alternatives and equivalents are possible. The embodiments are not limited by the embodiments described herein. Nor are the embodiments limited to any specific type of semiconductor device. Other additions, subtractions, or modifications are obvious in view of the present disclosure and are intended to fall within the scope of the appended claims.

1. A semiconductor device comprising:
a main dummy pattern; and
a test dummy pattern spaced apart from he main dummy pattern by a critical distance,
wherein the main dummy pattern has a damascene wiring structure including a via pattern having a first width and a wiring pattern formed on the via pattern, and the wiring pattern has a second width wider than the first width, and
wherein the test dummy pattern has a bottom surface and an upper surface, the bottom surface of the test dummy pattern has the first width and is substantially coplanar with a bottom surface of the via pattern, and the upper surface of the test dummy pattern is substantially coplanar with an upper surface of the wiring pattern.

2. The semiconductor device of claim 1, wherein the via pattern and the wiring pattern are formed with substantially the same material without boundary faces, and the test dummy pattern comprises a material substantially the same as that of the via pattern and the wiring pattern.

3. The semiconductor device of claim 1, further comprising a memory cell region and a peripheral and core (peripheral/core) region, wherein the peripheral/core region comprises a circuit element configured to control the memory cell region, and the main dummy pattern and the test dummy pattern are arranged in the peripheral/core region.

4. The semiconductor device of claim 1, further comprising:
a lower insulating interlayer arranged between the via pattern and a lower region of the test dummy pattern; and
an upper insulating interlayer arranged between the wiring pattern and an upper region of the test dummy pattern.

5. The semiconductor device of claim 1, further comprising a lower wiring structure arranged under the via pattern and the wiring pattern and electrically connected with the via pattern and the wiring pattern.

6. A semiconductor device comprising:
a semiconductor substrate including a lower wiring structure;
a lower insulating interlayer arranged on the lower wiring structure;
an upper insulating interlayer arranged on the lower insulating interlayer;
a main dummy pattern including a via contact with a first width formed in the lower insulating interlayer and a trench wiring pattern formed on the via contact, the trench wiring pattern having a second width wider than the first width of the via contact; and
a test dummy pattern formed through the lower insulating interlayer and the upper insulating interlayer and having the first width,
wherein the test dummy pattern has an error of the main dummy pattern.

7. The semiconductor device of claim 6, wherein the test dummy pattern has a bottom surface substantially coplanar with a bottom surface of the via pattern, and the upper surface is substantially coplanar with an upper surface of the wiring pattern.

8-12. (canceled)

13. A method of inspecting an error, the method comprising:
providing a lower wiring structure;
forming a main dummy pattern and a test dummy pattern on the lower wiring structure, the main dummy pattern including a via contact with a first width and a trench wiring pattern having a second width wider than the first width of the via contact, the test dummy pattern spaced apart from the main dummy pattern by no less than a critical distance, the test dummy pattern having a width substantially the same as that of the via contact, and the test dummy pattern having a height substantially the same as that of the main dummy pattern; and
testing the test dummy pattern to determine an error of the main dummy pattern based on an error of the test dummy pattern.

14. The method of claim 13, wherein testing the test dummy pattern comprises:
irradiating a light to the test dummy pattern; and
detecting a fight reflected from the test dummy pattern to determine a contact error based on an intensity of the reflected light from the test dummy pattern.

15. The method of claim 14, wherein the light comprises an electron beam.

16. The method of claim 14, wherein detecting the light comprises detecting a secondary electron signal of the reflected light to determine the contact error based on an intensity of the secondary electron signal,

17. The method of claim 13, further comprising:
resetting process recipes of the main dummy pattern and the test dummy pattern in accordance with a contact error of the main dummy pattern, after predicting the contact error of the main dummy pattern.
